(19) United States
(12) Patent Application Publication
(10) Pub. No.: US 2006/0073978 A1
(43) Pub. Date: Apr. 6, 2006

(54) Method and apparatus for making continuous films of a single crystal material

(75) Inventors: Eric Chason, Barrington, RI (US); Clyde L. Briant, Barrington, RI (US)

Correspondence Address: HARRINGTON & SMITH, LLP, 4 RESEARCH DRIVE, SHELTON, CT, 06484-6212, US

(73) Assignee: Brown University, Providence, RI (US)

(21) Appl. No.: 10/544,818

(22) PCT Filed: Feb. 4, 2004
(86) PCT No.: PCT/US04/03125

§ 371 Date: Aug. 5, 2005

Related U.S. Application Data
(60) Provisional application No. 60/445,911, filed on Feb. 6, 2003.

(51) Int. Cl. H01L 39/24; C23C 14/18

(52) U.S. Cl. 505/434; 505/470; 427/528; 427/531

(57) ABSTRACT

A method for making continuous film of single crystal material by crystal deposition. The method includes providing a single crystal template ribbon formed as a continuous loop; epitaxially depositing a sacrificial layer on the single crystal template ribbon by passing the single crystal template ribbon through a first process chamber; passing the single crystal template ribbon with the sacrificial layer epitaxially deposited thereon through a second processing chamber, wherein a final layer including a single crystal material is epitaxially deposited thereon; and passing the single crystal template ribbon with the sacrificial layer and the final layer epitaxially deposited thereon through a third processing chamber, thereby removing the sacrificial layer and detaching the final layer, which is the continuous film of a single crystal material.

### CROSS REFERENCE TO RELATED APPLICATIONS

This application claims priority from Provisional U.S. Patent Application No. 60/445,911, filed on Feb. 6, 2003, incorporated herein by reference.

### TECHNICAL FIELD

This invention is directed to a method and apparatus for making continuous films of a single crystal material and, more particularly, to a method and apparatus for making such films by epitaxial deposition. The continuous films made by the invention have particular application for use as tape substrates in the manufacture of high temperature superconducting materials, as well as semiconductor materials and magnetic applications, among other applications.

### BACKGROUND

Superconductors can carry high current without loss of power due to resistance being reduced to zero below a critical temperature. Accordingly, research has been conducted to employ high temperature superconductors in applications, such as electromagnetics and power transmission lines. In high temperature superconducting materials, conducting tapes that can carry large electrical currents for power or high-flux magnet applications have not had a significant commercial impact because of the difficulty in fabricating these conducting tapes. A major difficulty is that grain boundaries in the superconducting material reduce the superconducting properties so that the films must consist of highly oriented grains. Although some grain misorientation is acceptable, the critical current in the superconductor drops off quickly if the spread in grain alignment becomes too large, such as on the order of five degrees or more.

Known high temperature superconducting tapes include bismuth based and yttrium based high temperature superconducting materials. The yttrium based tapes are more difficult to fabricate than the bismuth based tapes, but have the advantage of being desirable for use in a high magnetic field. However, yttrium based tapes, such as Y₁Ba₂Cu₃O₇₋ₓ (“YBCO”), generally have poor mechanical properties and thus must be manufactured in a way to improve their properties.

One known method of manufacturing YBCO superconductor tapes is to form a YBCO film(s) on a tape substrate. One approach employs multilayers of high temperature superconducting thin films of the YBCO family deposited by sputtering or electrodeposition onto tapes of a highly oriented substrate. The substrate is typically a Ni or Ni alloy that has been oriented by a rolling and annealing process known as RaBITS (rolling assisted biaxial texture). Although this process is useful, it often results in a textured substrate having a spread of grain orientation on the order of about seven degrees. As mentioned above, although some grain nisorientation is acceptable, the critical current in the superconductor drops off quickly if the spread in grain aliginment becomes too large.

Single crystal materials are generally known to have a minute to non-existent degree of grain nisorientation because of the lack of grain boundaries in these materials. Electrochemical Production of Single-Crystal Cu—Ni Strained Layer Superlattices On Cu (100), Moffat T P, Journal of the Electrochemical Society, 142 (11): 3767-3770, November 1995 describes singe-crystal Cu—Ni superlattices grown on Cu(100) from an electrolyte and generally describes epitaxial deposition of single crystal Cu—Ni materials. However, despite these advances, progress has not been made in the development of single crystal continuous films by epitaxial deposition or such tape substrates of a single crystal continuous film type that can be used for applications such as high temperature superconducting materials.

One of the reasons that epitaxial deposition of single crystal materials has not proved commercially viable is that it is costly to produce single crystal materials and it would thus be cost prohibitive to form a large continuous film of epitaxially deposited layers of a single crystal material. In addition, there are various inherent chemical difficulties in preparing single crystal materials, some of which are described in U.S. Pat. No. 5,314,869.

Accordingly, there exists a need for continuous films of single crystal materials made by epitaxial deposition. There is a further need for such elongated materials that may be employed as high temperature superconducting tape substrates to enhance the current carrying capabilities of the high temperature superconducting materials. The present invention addresses these needs and others.

### SUMMARY

The foregoing and other problems are overcome, and other advantages are realized, in accordance with the presently preferred embodiments of these teachings.

In accordance with one embodiment of the invention, there is provided a method for making a continuous film of a single crystal material by epitaxial deposition. This method comprises providing a single crystal template ribbon formed as a continuous loop. The method further comprises epitaxially depositing a sacrificial layer on the single crystal template ribbon by passing the single crystal template ribbon through a first processing chamber. The method then provides for passing the single crystal template ribbon with the sacrificial layer epitaxially deposited thereon through a second processing chamber, wherein a final layer comprising a single crystal material is epitaxially deposited thereon. The single crystal template ribbon with the sacrificial layer and the final layer epitaxially deposited thereon then passes through a third processing chamber, removing the sacrificial layer and thus detaching the final layer, which is the continuous film of a single crystal material.

In accordance with another embodiment of the invention, an apparatus for making a continuous film of a single crystal material by epitaxial deposition is disclosed. The apparatus comprises a single crystal template ribbon formed as a continuous loop; and a first processing chamber, wherein a sacrificial layer is epitaxially deposited on the single crystal template ribbon. The apparatus also comprises a second processing chamber, wherein a final layer comprising a single crystal material is epitaxially deposited on the single crystal template ribbon with the sacrificial layer epitaxially deposited thereon. The apparatus further comprises a third processing chamber, wherein the single crystal template ribbon with the sacrificial layer and the final layer epitaxially deposited thereon has the sacrificial layer removed, thus allowing the final layer to become detached and form a continuous film of single crystal material.

In accordance with yet another embodiment of the invention, there is provided a method for making a continuous film of a single crystal material by epitaxial deposition that can be used as the single crystal template ribbon in a subsequent method for making a continuous film of a single crystal material by epitaxial deposition. According to one aspect, a method for making a single crystal template ribbon comprises providing a continuous film of a single crystal material formed as a continuous loop. The method further comprises epitaxially depositing a sacrificial layer on the continuous film of single crystal material by passing the continuous film of single crystal material through a first processing chamber. The method then provides for passing the continuous film of single crystal material with the sacrificial layer epitaxially deposited thereon through a second processing chamber, wherein a final layer comprising a single crystal material is epitaxially deposited thereon. The continuous film of single crystal material with the sacrificial layer and the final layer epitaxially deposited thereon passes through a third processing chamber, removing the sacrificial layer and thus detaching the final layer, which is the single crystal template ribbon.

Another aspect of the invention provides a high temperature superconducting, semiconducting or magnetic material comprising a continuous film of a single crystal material made by epitaxial deposition, as described herein.

Further aspects of the invention provide flat panel displays, solar cells, space applications, disk drives, read/writeheads and magnetic media that may contain at least one high temperature superconducting material, semiconductor material or other suitable magnetic material and comprise a continuous film of a single crystal material made by epitaxial deposition, as also described herein.

### BRIEF DESCRIPTION OF THE DRAWINGS

The foregoing and other aspects of these teachings are made more evident in the following Detailed Description, when read in conjunction with the attached Drawings, wherein:

FIG. 1 schematically illustrates a method for making a continuous film of a single crystal material, and apparatus employed therefore, in accordance with an embodiment of the invention;

FIG. 2 schematically illustrates a continuous deposition process for single crystal films, in accordance with another embodiment of the invention; and

FIG. 3 illustrates the epitaxially layered material that has passed through the first and second processing chambers of an apparatus, in accordance with an embodiment of the invention.

### DETAILED DESCRIPTION

A continuous film of a single crystal material may efficiently and cost effectively be produced using the processes and apparatuses described herein. This resultant continuous film of a single crystal material may be made from any suitable single crystal material. For example, this film may generally be a continuous film of a metal, such as nickel, copper, silver, iron, palladium, platinum, aluminum, zinc and alloys thereof, with nickel or copper being preferred. However, any metals, alloys, ceramics or any electrically conductive oxide that is conducive to deposition of further superconducting or semiconducting layers or magnetic materials may also be used.

The continuous film of a single crystal material may be of any desirable size depending upon the application for which it is intended to be used. Each separate application will have is own set of preferred lengths, widths and thicknesses which can vary greatly depending upon the application. Generally the length will vary from about 0.1 inches to about 10,000 feet long. The width of the continuous film of a single crystal material may be generally from about 0.1 inches to about 60 inches and the general thickness of the continuous film of a single crystal material may be from about 0.1 microns to about 1 inch. For example, a tape made of the continuous film of single crystal material can be from about 0.1 inches to about 10,000 feet long, from about 0.5 inches to about 10 inches wide and 0.1 microns to about 1 inch thick, among other suitable measurements.

One may use different alternating single-crystal materials to form the afore-described continuous film of single crystal material. One example of such different alternating single-crystal metal materials is a copper template ribbon, a nickel sacrificial layer and a copper final layer. This is possible because single crystal metals have essentially no grain misorientation and the single crystal metal aligns itself with that of the single crystal metal upon which it is deposited. Some such combinations of alternative single crystal materials that may be epitaxially deposited upon one another despite being of a different metal are a copper template ribbon, a zinc sacrificial layer and a nickel final layer. In addition, one may use a nickel single crystal template ribbon, a zinc sacrificial layer and a nickel final layer. Various other combinations are possible including any metal that can be epitaxially deposited upon another metal and will depend upon the desired final layer, but may include additional metals such as, silver, iron, palladium, platinum, and aluminum. Still further, one may use alloys of any metal, such as the afore-mentioned metals to the extent that they provide for epitaxial deposition of successive layers. Preferably, the deposited material has the same crystal structure and similar spacing between atoms (lattice parameter) as that of the underlying material. The formation of these successive layers will be described in further detail below, in accordance with embodiments of the invention.

The formation of a continuous film of a single crystal material in accordance with one embodiment of the invention utilizes the epitaxial deposition of two layers. “Epitaxial” is used herein to refer to growth on a crystalline substrate of a crystalline substance that mimics the orientation of the substrate. The two epitaxially deposited layers in this embodiment may be deposited upon a single crystal template ribbon. The single crystal template ribbon serves as a substrate for the epitaxial deposition of the subsequent layers, which may be used in the formation of the continuous film of a single crystal film.

“Continuous” is used herein to refer to as unbroken and without severance and may not necessarily have a predetermined length, size and/or duration. A continuous length of film may have a length dimension that is a finite amount that may be predetermined. The continuous film of single crystal material also includes an unbroken amount that will have no severance therein and that is of no predetermined length or size. Continuous can also refer to the process herein in that it is a process that can continue for as long as one operates the apparatus of the invention.

The single crystal template ribbon may be formed by any suitable method. For example, the ribbon may be formed from a molten bath of a single phase material that may have a substrate or seed crystal introduced therein. The seed may then be pulled from the bath, which will draw out a single crystal material and can then be polished to flatness, if necessary. The single crystal template ribbon may be made of any suitable material although it is preferably a metal, such as nickel, copper, silver, iron, palladium, platinum, aluminum, zinc and alloys thereof, with nickel or copper being most preferred. It should be noted that the single crystal template ribbon is not necessarily process-ready allowing it to be fed continuously into a continuous loop from the molten bath. Instead, the single crystal template ribbon may preferably be formed separately and is not immediately ready for the process when it exits the molten bath of single crystal material.

In furtherance to the above, some single crystal materials are known to be acquired generally from a molten bath of a single crystal material. The single crystal material can be attached to a substrate of choice. Preferably, a metal substrate, such as those described above for the single crystal template ribbon is employed in embodiments of the invention. Most preferably the substrate is nickel, copper or zinc. The substrate can be introduced into the molten bath in the form of a wire or separate metal tape, which can then have- the single crystal material in the molten bath adhere thereto and be immediately removed or pulled from the molten bath, thereby producing a single crystal template ribbon on a metal substrate. There are methods known in the art for forming single crystal materials from a molten bath; see U.S. Pat. No. 5,314,869, whose contents are hereby incorporated by reference.

Further methods of creating a single crystal material template ribbon may include regional recrystalization, chemical baths, evaporation techniques and sputtering. The single crystal template ribbon may also be formed from single crystal nucleation sites and through chemical vapor deposition (CVD) of atomized particles onto a substrate, such as metals, alloys, ceramics or any electrically conductive oxide.

After the single crystal template ribbon is preferably formed from a molten bath, it can be fashioned into a suitable processing means, such as a loop or disc, and more preferably a continuous process loop. In the continuous processing loop, the single crystal template ribbon can have films epitaxially deposited thereon and subsequently removed while allowing the single crystal template ribbon to be recycled into subsequent continuous cycles. In addition, the formation of the single crystal template ribbon may be conducted in a manner to allow for its subsequent use in an apparatus of the current invention. For example, one may produce a continuous film of a single crystal material of equal or larger size than the original single crystal template ribbon. The equal or larger size continuous film of a single crystal material can then be used as the single crystal material template ribbon in a further process of the invention to obtain a continuous film of a single crystal material of desired size and length. This can reduce the cost of utilizing an individual single crystal metal bath exclusively for forming the single crystal template ribbon. One single crystal template ribbon formed from a molten bath of single crystal material can serve as the parent to limitless amounts of continuous films of single crystal material, which can serve as a single crystal template ribbon in additional processes of the invention.

The loop of single crystal template ribbon may be of any desirable size depending upon the application for which it is intended to be used. Each separate application will have is own set of preferred lengths, widths and thicknesses, which can vary greatly depending upon the application. Generally, the length will vary from about 0.1 inches to about 10,000 feet long. The width of the continuous film of a single crystal material may be generally from about 0.1 inches to about 60 inches and the general thickness of the continuous film of a single crystal material may be from about 0.1 microns to about 1 inch. For example, a tape made of the continuous film of single crystal material can be from about 0.1 inches to about 10,000 feet long, from about 0.5 inches to about 10 inches wide and 0.1 microns to about 1 inch thick, among other suitable measurements.

In addition, the single crystal template ribbon may be bound to any suitable substrate for mechanical strength during the process. Examples of suitable backing materials include any metal, polymeric or other substrates providing support for the single crystal template ribbon. In the case of polymeric backing materials, they can be spray coated onto the template ribbon and then be exposed to ultraviolet light. Preferably, the backing material is a metal substrate. The single crystal template ribbon may be bound to the backing material by any suitable methods, including bonding, gluing, soldering etc. Alternatively, the single crystal template ribbon may be merely guided by the supporting substrate during the process.

The continuous loop of single crystal template may be passed through one or more processing chambers wherein epitaxial deposition of subsequent layers occurs, as well as the subsequent removal and separation of some of those layers to produce the resultant desired continuous film of a single crystal material. Although any number of processing chambers may be used in the current invention, the number of processing chambers will be subject to various processing limitations and demands known to those skilled in the art.

In one embodiment of the invention, the continuous loop of single crystal template ribbon is passed through at least one processing chamber and, preferably, through at least three processing chambers. One or more chambers could be combined to facilitate a combination of epitaxial deposition or etching.

According to one embodiment, the first processing chamber has the single crystal template ribbon passed there through wherein an intermediate layer, which may also be referred to as a sacrificial layer, is deposited thereon. This may be accomplished via electrochemical deposition (ECD), physical vapor deposition (PVD) or chemical vapor deposition (CVD). U.S. Pat. No. 6,670,308 describes ECD processes, U.S. Pat. Nos. 6,214,712 and 5,061,654 describe PVD processes and U.S. Pat. Nos. 6,547,876 and 4,773,355 describe CVD processes; the contents of these patents are hereby incorporated by reference. Similarly, other deposition methods known in the art, such as liquid phase epitaxy, vapor-phase epitaxy and molecular beam epitaxy, sputtering, and evaporation, as well as PVD and laser ablation, may be employed for deposition of the layers described herein.

In accordance with an embodiment of the invention, the first processing chamber will conduct any one of ECD, PVD or CVD processing before the single crystal template ribbon with the sacrificial layer deposited thereon is passed to the second processing chamber. The sacrificial layer should be epitaxially deposited so that it is also a single crystal whose structure and orientation is related to the single crystal template ribbon insuring single crystal epitaxial deposition. This may be accomplished by using a different single crystal material as that of the underlying single crystal template ribbon layer. Using a different single crystal material may only be limited by the second material being epitaxially conformable to the first single crystal material. Preferable single crystal metal materials are nickel and copper. The sacrificial layer may be very thin because it will be typically subsequently removed in the etching process. Typical thickness of the sacrificial layer may be from about 0.001 microns to about 0.1 inches. The width and length of the sacrificial layer may only typically be limited by the width and length of the underlying single crystal template ribbon and may generally be the same width and length as mentioned above for the single crystal template ribbon.

In one embodiment of the invention, the sacrificial layer may be epitaxially deposited utilizing ECD (electrochemical deposition). This essentially involves reduction/oxidation reactions, redox reactions, which employ a suitable electrolytic solution and electrode material. The suitability of the electrolytic solution and electrode will be dependent on the material being electrochemically deposited. For example, salts of the metal being deposited may be dissolved in the electrolytic solution; the electrolytic solution should be a relatively good electrical conductor; and the pH of the electrochemical bath should be kept within a range necessary to avoid the evolution of hydrogen. The ECD may occur by passing the single crystal template ribbon through an electrochemical bath at any suitable rate such as, from about 0.001 inches to about 1 foot per second. This may be accomplished by electroplating or electroless plating processes. The chemical bath utilized in this method may contain dissolved salts of metals such as nickel, copper, silver, iron, palladium, platinum, aluminum, zinc and alloys thereof, with nickel and zinc being most preferred. The electrode utilized in this method may be made of metals, such as nickel, copper, silver, iron, palladium, platinum, aluminum, zinc and alloys thereof with platinum, copper, nickel and zinc being most preferred. Preferably, the temperature of the electrochemical bath may be between about 0 to about 100° C.

In another embodiment of the invention, in the use of PVD as the possible means of epitaxial deposition in the first processing chamber, the single crystal template ribbon may be passed into the presence of a vapor producing device, such as an evaporator or sputter source or laser ablation source. PVD involves evaporation from a liquid or solid phase material that preexists in the PVD apparatus. The PVD apparatus evaporates molecules of the liquid or solid phase material and directly deposits them on a substrate. To prevent any discontinuity that may occur in the use of PVD and to maintain continuity of the film, a PVD processing chamber may be constructed sufficiently large to accommodate the entire length or width of the desired continuous film of single crystal material. Preferably, the single crystal template ribbon will pass through the first processing chamber containing the PVD container at a rate of from about 0.001 inches to about 1 foot per second or any other suitable rate. It may be passed in front of a source of the desired epitaxially deposited sacrificial layer. For example, any single crystal material, such as nickel, copper, silver, iron, palladium, platinum, aluminum, zinc and alloys thereof, with nickel or zinc being preferred, may be employed. The PRD process may preferably be conducted at a temperature of from about 0 to about 500° C.

The PVD apparatus employed in embodiments of the invention typically may include an enclosure, such as a deposition chamber, which houses a vapor producing device which directs vapor phase material toward a substrate that passes through the enclosure. The source of vapor phase material may comprise sputtering or vacuum evaporation techniques and alternatively, a laser ablation apparatus, which produces a laser beam to ablate the surface of a target pellet to produce vapor phase material, as is known in the industry. Any other apparatus which produces vapor phase material, may alternatively be used in the embodiments of the invention.

In a further embodiment of the invention, in the use of CVD as the possible means of epitaxial deposition in the first processing chamber, the single crystal template ribbon may be passed into the presence of a vapor producing device, such as a spout or other atomizing means. CVD involves chemical reactions that transform gaseous molecules called precursor into a solid material in the form of a thin film or powder on the surface of a substrate. This may be accomplished by vaporization and transport of the precursor molecules into a reactor followed by diffusion of the precursor molecules onto the surface of the substrate wherein the precursor molecules go through adsorption to the surface. These adsorbed molecules then decompose and form into a solid film on the substrate. Preferably, if CVD is used in the first processing chamber, it will be conducted in a vacuum-sealed container. However, CVD can be conducted in the presence of oxygen or an inert gas. To prevent any discontinuity that may occur in the use of CVD and to maintain continuity of the film, a CVD processing chamber may be constructed sufficiently large to accommodate the entire length or width of the desired continuous film of single crystal material. Alternatively or in addition thereto, the CVD chamber could be operated at normal atmospheric pressure in a semi-sealed vessel. Preferably, the single crystal template ribbon will pass through the first processing chamber containing the CVD vacuum-sealed container at a rate of from about 0.001 inches to about 1 foot per second or any other suitable rate. It may be passed in front of a source of the desired epitaxially deposited sacrificial layer. For example, any single crystal material, such as nickel, copper, silver, iron, palladium, platinum, aluminum, zinc and alloys thereof, with nickel or zinc being preferred, may be employed. The CVD process may preferably be conducted at a temperature of from about 0 to about 1500° C.

The CVD apparatus employed in embodiments of the invention typically may include an enclosure, such as a deposition chamber, which houses a source of vapor phase or precursor material. The source directs vapor phase or precursor material toward a substrate that passes through the enclosure. The source of vapor phase or precursor material may comprise gas sources, liquid sources or solid sources, as is known in industry. Any other apparatus, which produces vapor phase or precursor material, may alternatively be used in the embodiments of the invention.

The film exiting the first processing chamber, whether it has undergone ECD, PVD, CVD or another suitable process, will advantageously contain a single crystal template ribbon with a sacrificial layer epitaxially deposited thereon. This single crystal template ribbon with a sacrificial layer epitaxially deposited thereon may then be passed through a second processing chamber where a final layer may be epitaxially deposited thereon. This final layer may also be deposited by any one of ECD, CVD or other suitable methods, as described above with respect to the first processing chamber. The final layer is typically not limited by the length of the single crystal template ribbon. That is, the final layer may be drawn off of the current apparatus and collected as long as the process continues to operate.

If ECD is used as the epitaxial deposition means in the second processing chamber, then the single crystal template ribbon with a sacrificial layer epitaxially deposited thereon may be passed through the chemical bath at a rate of from about 0.001 inches to about 1 foot per second or at any other suitable rate. Preferably, the chemical bath in the second processing chamber contains dissolved salts of metals, such as nickel, copper, silver, iron, palladium, platinum, aluminum, zinc and alloys thereof, with nickel or copper being preferred. An electrode utilized in this method may be made of metals, such as nickel, copper, silver, iron, palladium, platinum, aluminum, zinc and alloys thereof, with platinum, copper, and nickel being most preferred. The electrochemical deposition in the second processing chamber may occur through electroplating or electroless plating in the same manner as in the first processing chamber. If PVD or CVD is utilized in the second processing chamber, then the process may be conducted in the manner described above with respect to the first processing chamber, with nickel, copper and zinc being the preferred metals.

The film exiting the second processing chamber includes the single crystal template ribbon with the sacrificial layer and final layer epitaxially deposited thereon, which may then enter a third processing chamber. In keeping with embodiments of the invention, the single crystal template ribbon with the sacrificial layer and the final deposited thereon may be separated in the third processing chamber. In the third processing chamber, the single crystal template ribbon with the sacrificial layer and final layer epitaxially deposited thereon may then advantageously have the sacrificial layer chemically or electrochemically removed. The chemical removal can comprise chemical etching. Any other suitable removal method may also be employed. The sacrificial layer should be able to be removed by etching more easily than the single crystal template ribbon layer or the final layer to allow for the subsequent separation and removal of the final layer, which forms the continuous film of a single crystal material. Chemical etching may involve passing the single crystal template ribbon with the sacrificial layer and final layer epitaxially deposited thereon through at least one chemical bath of acidic solution, preferably nitric acid. Alternative acidic solutions known to those skilled in the art may be used, as well, such as sulfuric acid and hydrofluoric acid. The bath will typically etch from the exposed sides of the single crystal template ribbon with the sacrificial and final layer epitaxially deposited thereon. This may be accomplished in a manner that will chemically remove the sacrificial layer quickly without significantly degrading the single crystal template ribbon or the final layer. The sacrificial layer typically remains in the chemical etching bath, which may periodically be refreshed with new acid or electrochemical solution. The removal of the sacrificial layer inherently causes a separation of the remaining two layers. Alternatively, in another embodiment of the invention, this may be accomplished through electrochemical etching whose processes are well known to those skilled in the art.

In accordance with alternate embodiments of the invention, alternating processes of epitaxial deposition and etching may be employed in the first, second and third processing chambers. For example, the first processing chamber could involve exclusive use of ECD followed by exclusive use of PVD in the second processing chamber, or vice-versa, in addition to using CVD in either the first or second processing chamber. Either process then could be followed by either electrochemical or chemical etching in the third processing chamber, among other possible combinations.

Regardless of the selection of the particular processes for each processing chamber, upon exiting the third processing chamber the separated single crystal template ribbon may continue to pass into another cycle of the continuous loop while the separated final layer is advantageously collected. For example, the separated final layer may be collected by winding it around a spool to form the resultant continuous film of a single crystal material. The single crystal template ribbon may then be passed through a cleaning process, which may include an acid bath comprising nitric, sulfuric or other suitable acids or the single crystal template ribbon may undergo electropolishing. Alternatively, there may be one or more cleaning processes depending on the extent of impurity present on the single crystal template ribbon. To avoid excessive deterioration of the single crystal template ribbon through multiple exposures to the chemical bath, the single crystal template ribbon may be recoated with additional single crystal template material, as necessary. Any suitable processes, such as evaporation, sputtering and chemical vapor deposition, may be employed in the recoating process. Similarly, the deposition processes of the invention described herein may be used.

The continuous film of a single crystal material produced by embodiments of the invention may have no grain misorientation or at the most may contain negligible amounts of grain misorientation. In one embodiment of the invention, the resultant continuous film of a single crystal material may have a backing material adhered to one side in order to improve its mechanical properties prior to being wound onto the spool. Suitable backing materials may include polymers, such as polymethylmethacrylate, pethyleneterephthalate, polyvinyl acetate, polystyrene, polyvinylchloride and any suitable polymer that may provide mechanical strength to the continuous film of single crystal material.

In another embodiment of the invention, the continuous film of a single crystal material, with or without the aforementioned backing material, may be used immediately, or within processing systems at a later time, by having at least one superconducting layer, semiconducting layer or other suitable layer deposited thereon. Preferably, the superconducting layer is a high temperature superconducting layer, such as those in the YBCO family. However, alternative forms of superconducting films may be employed. In addition to superconducting layers, one may deposit one or more semiconducting layers or combinations of superconducting and semiconducting layers. Furthermore, one may use the continuous single crystal film in photovoltaic materials, magnetic materials and precursors of superconductors.

In accordance with a further embodiment of the invention, there may be multiple steps following deposition of the afore-described final layer in the second processing chamber before separation in the third processing chamber. For example, the afore-described single crystal template ribbon with the sacrificial layer epitaxially deposited therein may be passed into the second processing chamber for deposition of the afore-described final layer. One or more superconducting or non-superconducting layers may then be deposited on this final layer in one or more steps prior to the afore-described etching step in the third processing chamber. In the third processing chamber, the etchant removes the sacrificial layer thereby advantageously detaching the final layer and bound layers deposited thereon. Thus, this product may advantageously comprise a superconducting tape and not just a substrate for a superconductor, in one embodiment of the invention.

The additional one or more deposited layers may be made of any suitable material, including, superconducting YBCO and ReBCO films, among other known superconducting materials. Similarly, any suitable non-superconducting material may also be employed, depending upon the desired application. Suitable materials include, but are not limited to, single or non-single crystal materials of the various layers previously described herein. Any desired thickness may also be employed for these layers, as well as the other layers described herein. Similarly, these layers may also be deposited by any suitable means, including Blown sputtering and electrodeposition techniques, and may be epitaxially or non-epitaxially deposited. These additional layers may be deposited in the second processing chamber by the techniques described herein or, alternatively, deposited in a chamber separate from that of the second processing chamber. As one non-limiting example, a nickel single crystal layer may be epitaxially deposited upon the sacrificial layer in the second processing chamber. This may be followed by the epitaxial or non-epitaxial deposition of one or more superconducting layers. In the third processing chamber, the superconducting layers deposited on the underlying nickel single crystal material are separated as a unit from the single crystal template ribbon by chemically or electrochemically etching the intermediate epitaxially deposited sacrificial layer. The sacrificial layer is etched more quickly than the other layers. The separated superconducting layers and underlying epitaxially deposited nickel layer may advantageously form a superconducting tape, which can be collected as described above. See U.S. Pat. Nos. 5,439,876; 6,670,308 and 5,964,966, the contents of each of which are incorporated by reference, for further descriptions of superconducting materials and material depositions.

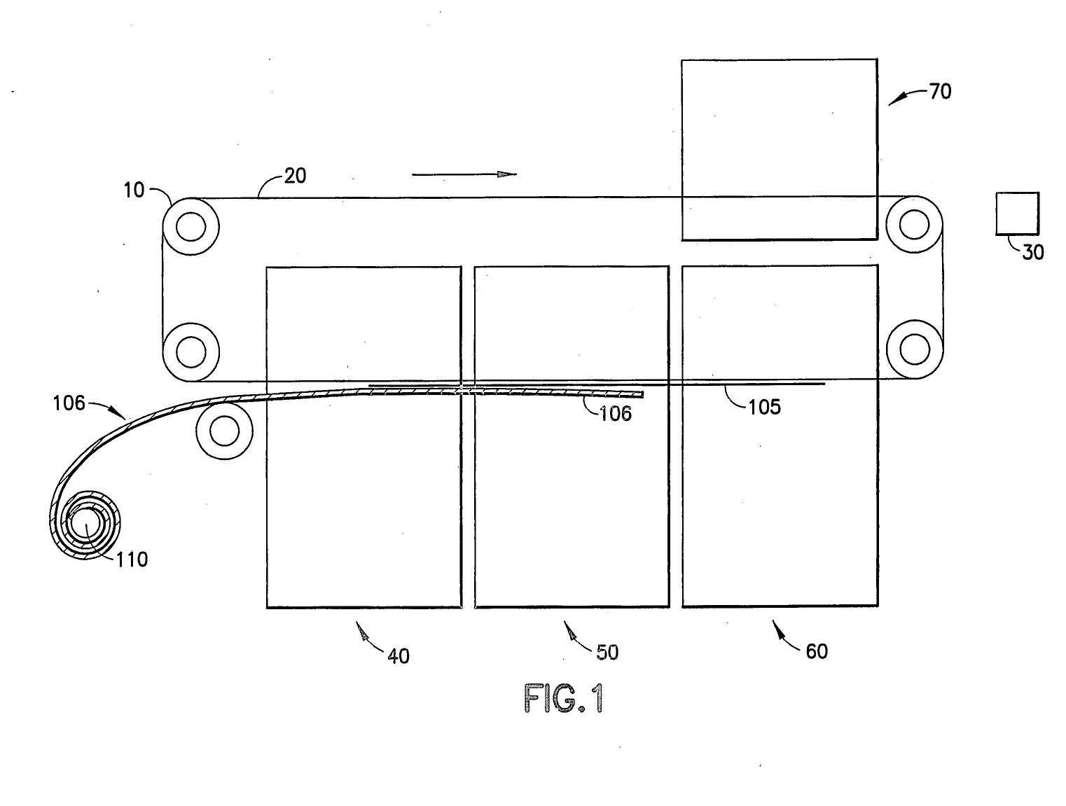

A non-limiting example of the apparatus for implementing the processes described herein is also provided. The generally provided apparatus for making a continuous film of a single crystal material, according to an embodiment of the invention, is set forth in FIG. 1. As shown therein, there is a molten bath source 30, which provides for a single crystal template ribbon 20 to a continuous loop on rollers 10. The molten bath source 30 does not directly feed the continuous loop of single crystal material 20, rather the single crystal material that is drawn from the molten bath is separately flattened and formed into a continuous loop of single crystal material 20, which is then used in the current process. The single crystal template ribbon 20 enters the first processing chamber 60 where it has sacrificial layer 105 epitaxially deposited thereon. This is followed by the epitaxial deposition of final layer 106 in second processing chamber 50. The single crystal template ribbon 20 with epitaxially deposited sacrificial layer 105 and final layer 106 is then fed through the third processing chamber 40. Third processing chamber 40 provides for separation of final layer 106 by the chemical or electrochemical removal of sacrificial layer 105. Final layer 106 is thus the continuous film of single crystal material, which is optionally wound onto spool 110, while the single crystal template ribbon 20 is recycled into the loop and put through cleaning bath 70.

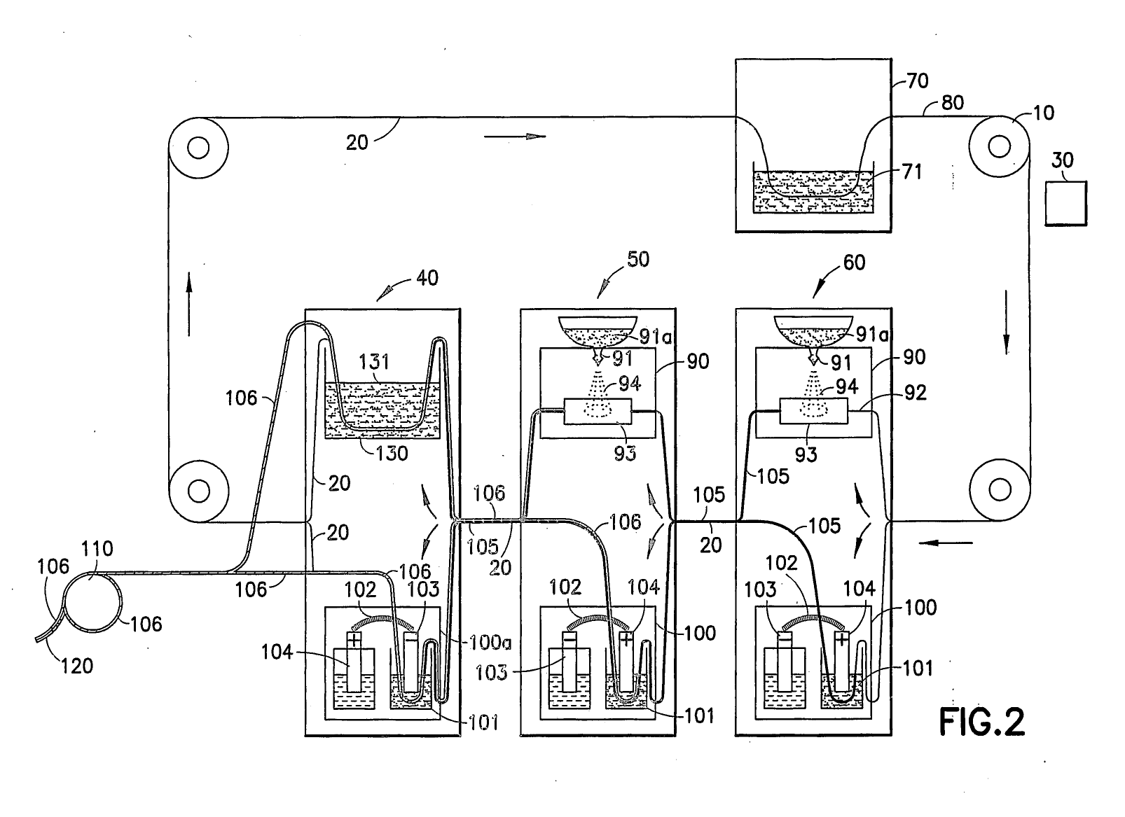

A further embodiment of an apparatus employed in embodiments of the invention is set forth in FIG. 2. As shown therein, there is a molten bath source 30, which provides for a single crystal template ribbon 20 in a continuous loop on rollers 10. The molten bath source 30 does not directly feed the continuous loop of single crystal material 20, rather the single crystal material that is drawn from the molten bath is separately flattened and formed into a continuous loop of single crystal material 20 which is then used in the current process. The single crystal template ribbon 20 enters first processing chamber 60 and is then routed to the ECD bath chamber 100, PVD apparatus 90 or a vacuum-sealed CVD apparatus.

The ECD apparatus of the first processing chamber 60 can have the continuous cycle of single crystal template ribbon 20 routed to an ECD apparatus chamber 100 where it enters an electrolytic solution 101 that contains a dissolved metal salt. The deposition is provided by electrodes 103, 104 through a salt bridge or wire 102 resulting in the epitaxial deposition of the sacrificial layer 105 on the single crystal template ribbon 20, which are both then routed to the second processing chamber 50.

Alternatively to ECD and as described above, in the PVD apparatus there is a PVD apparatus enclosure 90, such as a deposition chamber housing a vapor producing device 91. The vapor-producing device 91 directs vapor phase material 94 toward a substrate 97 which is enlarged for illustration 93 within the enclosure 90. The vapor producing device 91 may be an evaporator or sputter source or laser ablation source. The vapor producing device 91 evaporates a preexisting liquid or solid phase material 91a into the vapor phase material 94, which then has the evaporated molecules of the vapor phase material 94 directly deposited on the substrate 92, resulting in the epitaxial deposition of the sacrificial layer 105 on the single crystal template ribbon 20. Both materials are then routed to the second processing chamber 50.

Alternatively to either ECD or PVD the single crystal template ribbon 20 is exposed to a CVD apparatus (not shown) in first processing chamber 60, which can then epitaxially deposit sacrificial layer 105 prior to routing both materials to the second processing chamber 50.

The same three epitaxial deposition alternatives are available in second processing chamber 50 as were available in first processing chamber 60. The epitaxially deposited sacrificial layer 105 on the single crystal template ribbon 20 can be routed to similar ECD apparatus 100, PVD apparatus enclosure 90 or CVD apparatus (not shown), any of which may epitaxially deposit final layer 106 on top of sacrificial layer 105 and single crystal template ribbon 20 in the same manner as in first processing chamber 60.

The epitaxially deposited final layer 106 on top of sacrificial layer 105 and single crystal template ribbon 20 is then routed to third processing chamber 40 where it may enter chemical etching bath 130 containing an acidic solution 131, which etches sacrificial layer 105 quicker then final layer 106 or single crystal template ribbon 20. Alternatively, in third processing chamber 40 the epitaxially deposited final layer 106 on top of sacrificial layer 105 and single crystal template ribbon 20 is routed to an electrochemical etching apparatus 100a. Apparatus 100a can be the same as the ECD apparatus chamber 100 of both first processing chamber 60 and second processing chamber 50 except that electrodes 103, 104 are switched in position to provide electrochemical etching of the sacrificial layer 105 and the electrolytic solution 101 is an alternative electrolytic solution to any electrolytic solution used for ECD previously and one that will provide for electrochemical etching. Immediately thereafter, either in third processing chamber 40 as is shown in FIG. 2 or outside third processing chamber 40 (not shown), the final layer 106 is separated from single crystal template ribbon 20. This separation may occur manually or through automated methods. The single crystal template ribbon 20 then continues as a continuous loop and is sent to at least one cleaning chamber 70 where an acid bath 71 removes any impurities from the continuous loop of single crystal template ribbon 20. The final layer 106 may then be wound around spool 110 with or without a backing material 120 and used in further processes, as described above.

While the ECD, PVD or CVD processes in FIG. 2 are shown as part of the same overall apparatus, it is understood that these processes may each be employed in a separate apparatus.

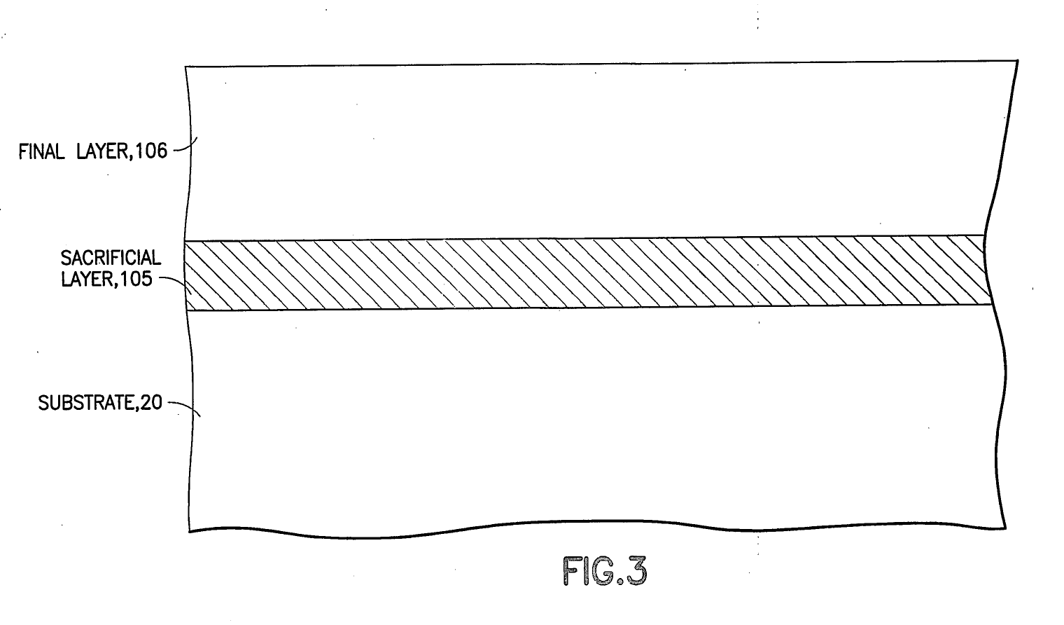

FIG. 3 shows the epitaxially deposited layers as they leave second processing chamber 50, in accordance with an embodiment of the invention. The substrate is single crystal template ribbon 20, the intermediate layer is the sacrificial layer 105 and top layer is final layer 106, which forms the continuous film of single crystal material 106.

Advantages of embodiments of the invention include the ability to produce a continuous film of single crystal material in a cost efficient manner without exclusively utilizing expensive single crystal metals. The continuous process allows for the production of continuous films of single crystal materials, which can then serve as a single crystal template ribbons in further processes without utilizing the expensive exclusive use of molten bath obtained single crystal material. Thus, with one process utilizing an original single crystal template ribbon obtained from a molten bath of single crystal material, in accordance with an embodiment of the invention, one may produce limitless amounts of continuous film of single crystal material, which can serve as the single crystal template ribbon in subsequent processes or apparatuses. This can then dramatically decrease the need for the expensive single crystal material. This can be accomplished in a continuous industrial process without separate treatments in differing apparatus that prevent continuity of the film, as well as expose the film to multiple chances for decreasing its purity. The additional steps that would be entailed in operating the current process in a piece-meal fashion may subject the film to contamination and other environmental factors. Additionally, the length of the continuous film may only be limited by the extent of the recycling of the process and by the desired length of the continuous film depending on its intended application.

Moreover, embodiments of the invention may produce a continuous film of single crystal material deposited on any suitable substrate, such as metals, alloys, ceramics or any electrically conductive oxide. If such a substrate is used, it is desirable that the continuous film of single crystal material be epitaxially deposited on the substrate, that being, that the continuous film is one whose crystalline lattice is nearly perfectly aligned with the lattice parameters of the substrate on which it is deposited. The continuous film of single crystal material may be used to form a superconductor tape substrate or semiconductor tape substrate, which can have a support layer underneath the continuous film of single crystal material, and preferably under the single crystal metal material, to form a supported superconductor tape substrate or semiconductor substrate. Similarly, superconducting tapes may be advantageously formed, in accordance with embodiments of the invention.

Additionally, a continuous film of a single crystal material with the at least one high temperature superconducting layer, semiconducting layer, magnetic layer or other suitable layer deposited thereon in accordance with embodiments of the invention may advantageously be used in many industrial and commercial applications. For instance, suitable applications include superconducting cables for power transmission, flat panel display devices, such as monitors for computers and other electronic equipment, and magnetic media, such as disk drives and read/writeheads. One may also employ embodiments of the invention in space applications and solar cell or solar-powered devices. Furthermore, the continuous film of single crystal material can also be used in the fabrication of semiconductor devices, those devices being known to those skilled in the art and entailing various types of computer applications.

Thus, while this invention has been described in the context of presently preferred embodiments, those skilled in the art should appreciate that the disclosed embodiments are not to be construed as being limitations upon the scope and practice of this invention.

What is claimed is:

1. A method for making a continuous film of a single crystal material by epitaxial deposition comprising the steps of:
providing a single crystal template ribbon formed as a continuous loop;
epitaxially depositing a sacrificial layer on the single crystal template ribbon by passing the single crystal template ribbon through a first processing chamber;
passing the single crystal template ribbon with the sacrificial layer epitaxially deposited thereon through a second processing chamber, wherein a final layer comprising a single crystal material is epitaxially deposited thereon; and
passing the single crystal template ribbon with the sacrificial layer and the final layer epitaxially deposited thereon through a third processing chamber, wherein the sacrificial layer is removed and the final layer becomes detached to form the continuous film of the single crystal material.

2. The method of claim 1, wherein the continuous film of a single crystal material is a continuous film of a metal selected from the group consisting of nickel, copper, silver, iron, palladium, platinum, aluminum, zinc and alloys thereof.

3. The method of claim 1, wherein the single crystal template ribbon is a metal selected from the group consisting of nickel, copper, silver, iron, palladium, platinum, aluminum, zinc and alloys thereof.

4. The method of claim 1, wherein the single crystal template ribbon is formed by the pulling of single crystal material from a molten bath and fashioning it into a continuous loop.

5. The method of claim 1, wherein in the first processing chamber the sacrificial layer is deposited by electrochemical deposition, physical vapor deposition or chemical vapor deposition.

6. The method of claim 5, wherein the electrochemical deposition in the first processing chamber occurs by passing the single crystal template ribbon through an electrochemical bath at a rate of from about 0.001 inches to about 1 foot per second.

7. The method of claim 6, wherein the electrochemical bath in the first processing chamber contains an electrolytic solution of at least one metal salt.

8. The method of claim 7, wherein in the first processing chamber the electrochemical deposition occurs by electroplating or electroless plating.

9. The method of claim 5, wherein in the first processing chamber the physical vapor deposition occurs by passing the single crystal template ribbon in front of a vapor producing device of nickel or zinc inside a vacuum deposition chamber at a rate of from about 0.001 inches to about 1 foot per second.

10. The method of claim 1, wherein the sacrificial layer is a continuous film of nickel, copper, silver, iron, palladium, platinum, aluminum, zinc and alloys thereof.

11. The method of claim 1, wherein in the second processing chamber the single crystal template ribbon with the sacrificial layer epitaxially deposited thereon has a final layer deposited thereon by electrochemical deposition or physical vapor deposition or chemical vapor deposition.

12. The method of claim 11, wherein the electrochemical deposition in the second processing chamber occurs by passing the single crystal template ribbon with the sacrificial layer epitaxially deposited thereon through an electrochemical bath at a rate of from about 0.001 inches to about 1 foot per second.

13. The method of claim 12, wherein the electrochemical bath in the second processing chamber contains an electrolytic solution of at least one metal salt.

14. The method of claim 13, wherein the electrochemical deposition in the second processing chamber occurs by electroplating or electroless plating.

15. The method of claim 11, wherein the physical vapor deposition in the second processing chamber occurs by passing the single crystal template ribbon with the sacrificial layer epitaxially deposited thereon in front of a source of nickel or copper inside a vacuum deposition chamber at a rate of from about 0.001 inches to about 1 foot per second.

16. The method of claim 1, wherein the final layer is a continuous film of nickel, copper, silver, iron, palladium, platinum, aluminum, zinc and alloys thereof.

17. The method of claim 1, wherein in the third processing chamber the single crystal template ribbon with the sacrificial layer and the final layer epitaxially deposited thereon has the sacrificial layer chemically or electrochemically removed and the final layer becomes detached to form the continuous film of the single crystal material.

18. The method of claim 17, wherein in the third processing chamber the sacrificial layer is chemically removed through chemical etching.

19. The method of claim 18, wherein in the third processing chamber the chemical etching occurs in a maimer that the sacrificial layer is chemically etched more easily than the final layer.

20. The method of claim 19, wherein the final layer becomes detached from the single crystal template ribbon after leaving the third processing chamber and is wound around a spool to form a spool of continuous film of the single crystal material.

21. The method of claim 20, wherein the spooled continuous film of single crystal material has a length of from about 0.1 inches to about 10,000 feet, a width of from about 0.1 inch to about 60 inches, and a thickness of from about 0.1 microns to about 1 inch.

22. The method of claim 21, wherein the continuous film of single crystal material has substantially no grain boundary misorientation.

23. The method of claim 22, wherein the continuous film of single crystal material has subsequently deposited thereon at least one semiconducting layer.

24. The method of claim 22, wherein the continuous film of single crystal material has subsequently deposited thereon at least one superconducting layer.

25. The method of claim 22, wherein the continuous film of single crystal material has subsequently deposited thereon at least one superconducting layer and at least one semiconducting layer.

26. The method of claim 24, wherein the superconducting layer is at least one high temperature superconducting layer of a YBCO material.

27. A device comprising at least one superconducting layer deposited on at least one continuous film of single crystal material as prepared by the process of claim 24.

28. A magnetic medium comprising at least one continuous film of single crystal material as prepared by the process of claim 24.

29. The magnetic medium of claim 28, wherein the magnetic media is selected from the group consisting of disk drives and read/writeheads.

30. A superconducting or semiconducting material comprising a continuous film of a single crystal material made by the method of claim 1.

31. An apparatus for making a continuous film of a single crystal material by epitaxial deposition comprising a
a single crystal template ribbon formed as a continuous loop;
a first processing chamber wherein a sacrificial layer is epitaxially deposited on the single crystal template ribbon
a second processing chamber, wherein a final layer comprising a single crystal material is epitaxially deposited on the single crystal template ribbon with the sacrificial layer epitaxially deposited thereon; and
a third processing chamber, wherein the single crystal template ribbon with the sacrificial layer and the final layer epitaxially deposited thereon has the sacrificial layer removed allowing the final layer to become detached and form a continuous film of single crystal material.

32. A continuous film of single crystal material made by the method of claim 1.

33. The continuous film of claim 32, a portion of which is used to form a superconductor tape substrate or a semiconductor substrate.

34. A method for making a continuous film of a single crystal metal material substrate by epitaxial deposition comprising the steps of:
providing a single crystal template ribbon formed as a continuous loop;
epitaxially depositing a sacrificial layer on the single crystal template ribbon by
passing the single crystal template ribbon through a first processing chamber;
passing the single crystal template ribbon with the sacrificial layer epitaxially deposited thereon through a second processing chamber, wherein a final metal layer comprising a single crystal metal material is epitaxially deposited thereon; and
passing the single crystal template ribbon with the sacrificial layer and the final metal layer epitaxially deposited thereon through a third processing chamber, wherein the sacrificial layer is removed and the final metal layer becomes detached to form the continuous film of the single crystal metal material substrate.

35. The method of claim 34, wherein the continuous film of the single crystal metal material substrate is used to produce a superconductor tape substrate or a semiconductor substrate.

36. The method of claim 35, further comprising depositing a support layer underneath the continuous film of single crystal metal material to form a supported substrate for a superconductor or semiconductor material.

37. A method of making a single crystal template ribbon comprising the steps of:
providing a continuous film of a single crystal material formed as a continuous loop;
epitaxially depositing a sacrificial layer on the continuous film of single crystal material by passing the continuous film of single crystal material through a first processing chamber;
passing the continuous film of single crystal material with the sacrificial layer epitaxially deposited thereon through a second processing chamber, wherein a final layer comprising a single crystal material is epitaxially deposited thereon; and
passing the continuous film of single crystal material with the sacrificial layer and the final layer epitaxially deposited thereon through a third processing chamber, wherein the sacrificial layer is removed and the final layer becomes detached to form the single crystal template ribbon.

38. A continuous film of a single crystal material having a length up to about 10,000 feet.

39. The continuous film of claim 38, wherein the single crystal material comprises a single crystal metal material.

40. The method of claim 1, further comprising:
depositing at least one additional layer on the final layer prior to passing the single crystal template ribbon with sacrificial layer and the final layer thereon through the third processing chamber;
passing the single crystal template ribbon with the sacrificial layer, the final layer and the at least one additional layer thereon through the third processing chamber, wherein the sacrificial layer is removed and the final layer with the at least one additional layer thereon becomes detached.

41. The method of claim 40, wherein the at least one additional layer is a superconducting layer.

42. A superconducting tape made by the method of claim 41.
